(19) United States
(12) Patent Application Publication
(10) Pub. No.: US 2013/0008704 A1
(43) Pub. Date: Jan. 10, 2013

(54) BRIDGING STRUCTURE OF A TOUCH PANEL

(76) Inventor: CHIH-SHUN CHANG, Taipei County (TW)

(21) Appl. No.: 13/177,519

(22) Filed: Jul. 6, 2011

(51) Int. Cl. H05K 1/11

(52) U.S. Cl. 174/262

(57) ABSTRACT

A bridging structure of a touch panel is provided, which includes a transparent conducting layer, an insulating layer, and a conducting layer sequentially stacked on a transparent substrate. The transparent conducting layer includes the first and second transparent conducting portions, and the transparent conducting connection portions. The first and second transparent conducting portions are interlaced with each other. Each of the transparent conducting connection portions connects the adjacent first transparent conducting portions to each other along the first direction. The first transparent conducting portions and the transparent conducting connection portions can be electrically insulated from the second transparent conducting portions by the insulating layer. The conducting layer comprises the conducting connection portions, and the conductive via plugs formed in the insulating layer and located on the second transparent conducting portions. The conducting layer connects the adjacent second transparent conducting portions to each other along the second direction.

### BACKGROUND OF THE INVENTION

1. Field of the Invention

The present invention relates to a touch panel, and more particularly to a bridging structure of the touch panel, which includes a conducting layer including a plurality of conductive via plugs which connect the adjacent transparent conducting portions to each other.

2. The Prior Arts

Touch panels can provide display and control functions, which is user friendly and allows for quick and easy operation. Moreover, because the touch panel has a reduced size and is lightweight, it can be advantageously used in a wide variety of electronic devices such as mobile phones, flat computers, automated telling machines, automated vending machines, navigation devices, etc. In particular, because the capacitive touch panel can provide multi-touch control of an electronic system, it increasingly replaces the resistive touch panel.

Conventionally, the bridging structure in the capacitive touch panel includes an insulating layer formed on a transparent conducting layer (ITO), and a metal layer formed on the insulating layer for electrical connection. The insulating layer is used for insulating the transparent conducting portions in the direction X and the direction Y, such as described in Taiwan Patent No. M388686. However, the disadvantage of the conventional bridging structure of the touch panel is that the metal layer can be easily broken due to poor etching of an insulating layer or poor step covering ability. Moreover, the insulating layer may be defective, which will cause the occurrence of short-circuit along the direction X or Y.

Therefore, there is a need to provide a bridging structure comprising a conducting layer including a plurality of conductive via plugs connecting the adjacent transparent conducting portions to each other in order to solve the prior art problems.

### SUMMARY OF THE INVENTION

The objective of the present invention is to provide a bridging structure of a touch panel, which comprises a transparent conducting layer, an insulating layer, and a conducting layer sequentially stacked on a transparent substrate for forming a touch sensor structure. The transparent conducting layer comprises a plurality of the first transparent conducting portions, a plurality of the transparent conducting connection portions, and a plurality of the second transparent conducting portions. The first transparent conducting portions and the second transparent conducting portions are interlaced with each other. Each of the transparent conducting connection portions connects the adjacent first transparent conducting portions to each other along the first direction. The first transparent conducting portions and the transparent conducting connection portions are electrically insulated from the second transparent conducting portions by the insulating layer. The insulating layer has a plurality of through-holes located on the second transparent conducting portions. The conducting layer comprises a plurality of conducting connection portions and a plurality of conductive via plugs. The conducting layer connects the adjacent second transparent conducting portions to each other along the second direction.

The material of the transparent conducting layer comprises indium tin oxide (ITO).

The first transparent conducting portions and the second transparent conducting portions can have a square shape, a rectangular shape, a lozenge shape, a circular shape, an elliptical shape, or a polygonal shape. The transparent conducting connection portions can have a strip shape. The cross-sectional shape of the conductive via plug can have a square shape, a rectangular shape, or a circular shape.

Accordingly, when the touch panel of the present invention is manufactured, the number of photomasks can be reduced, and the insulating layer can cover the entire substrate to prevent the occurrence of short-circuits due to the poor etch or poor exposure. As a result, the bridging structure is more reliable.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is schematic views showing a bridging structure of a touch panel according to one embodiment of the present invention;

FIG. 2 is an enlarged view showing portion II of FIG. 1; and

FIG. 3 is a cross-sectional view taken along the line III-III of FIG. 2.

### DETAILED DESCRIPTION OF THE PREFERRED EMBODIMENTS

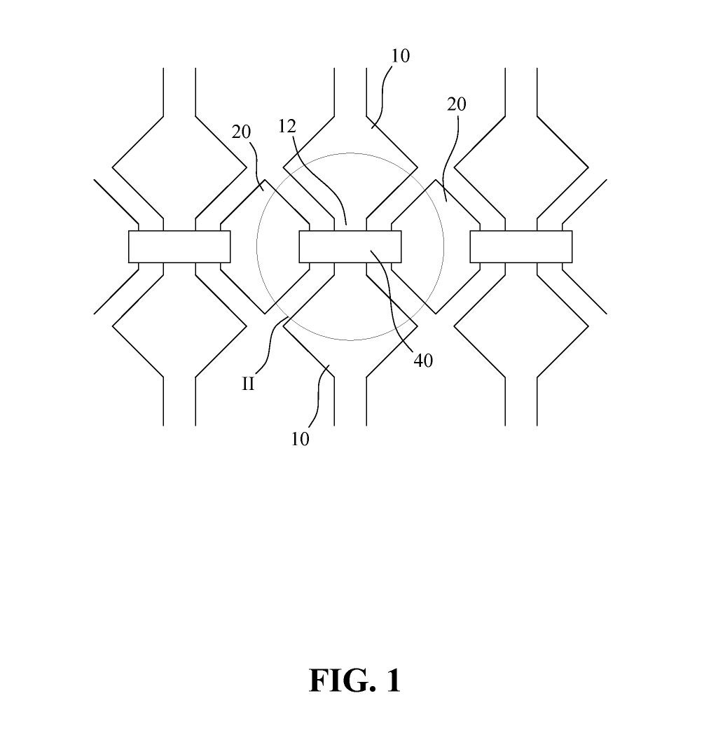

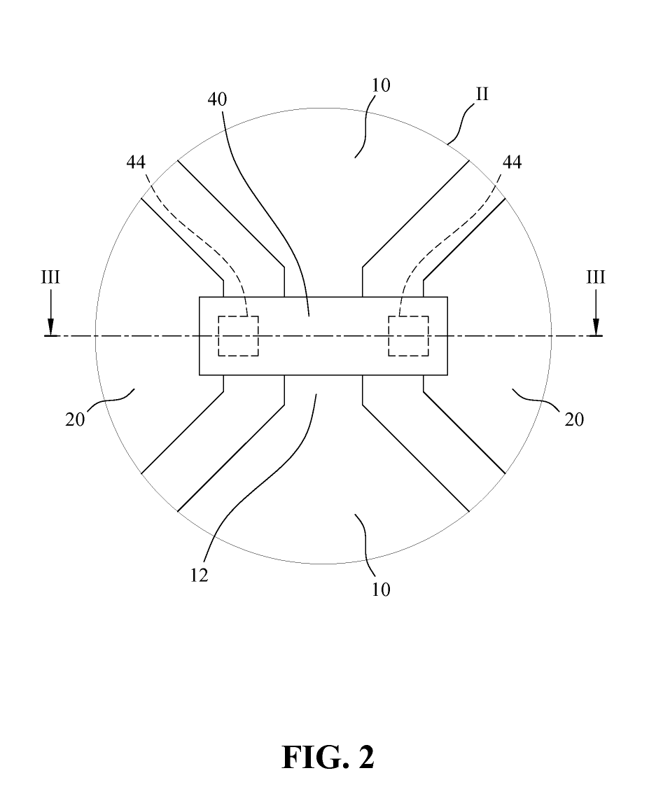

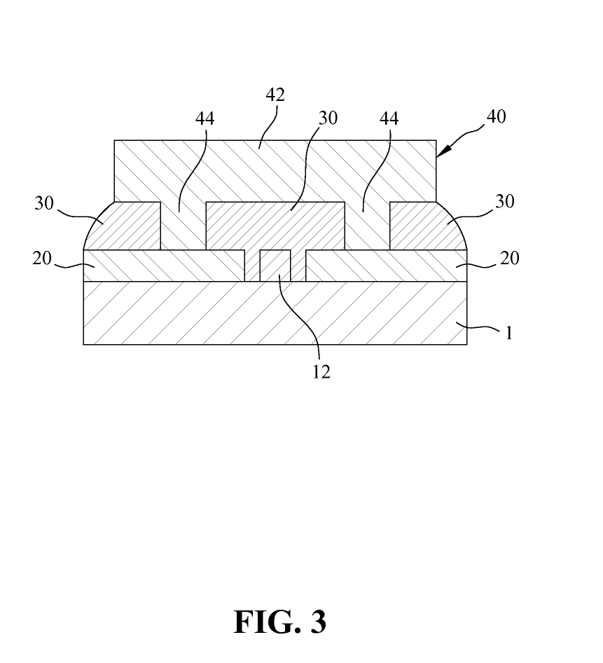

FIG. 1 is schematic views showing a bridging structure of a touch panel according to one embodiment of the present invention. FIG. 2 is an enlarged view showing portion II of FIG. 1. FIG. 3 is a cross-sectional view taken along the line III-III of FIG. 2. The bridging structure of the touch panel comprises a transparent conducting layer, an insulating layer 30, and a conducting layer sequentially stacked on a transparent substrate 1 for forming a touch sensor structure.

The transparent conducting layer comprises a plurality of the first transparent conducting portions 10, a plurality of the transparent conducting connection portions 12, and a plurality of the second transparent conducting portions 20. The first transparent conducting portions 10 and the second transparent conducting portions 20 are interlaced with each other. Each of the transparent conducting connection portions 12 connects the adjacent first transparent conducting portions 10 to each other along the first direction.

The insulating layer 30 covers the transparent conducting connection portions 12 so that the first transparent conducting portions 10 and the transparent conducting connection portions 12 are electrically insulated from the second transparent conducting portions 20 by the insulating layer 30. The insulating layer 30 has a plurality of through-holes located on the second transparent conducting portions 20. The conducting layer 40 comprises a plurality of conducting connection portions 42 and a plurality of conductive via plugs 44. The conducting layer 40 connects the adjacent second transparent conducting portions 20 to each other along the second direction.

It is noted that the conducting connection portion 42 with the two conductive via plugs 44 respectively electrically connected to the two adjacent second transparent conducting portions 20 is shown in FIGS. 2 and 3. However, it is to be understood that the present invention is not limited to this particular embodiment, and any number of the conductive via plugs 44 can be provided.

The first and second transparent conducting layers 10 and 20 can be made of indium tin oxide (ITO). The insulating layer 30 can be made of silicon dioxide (SiO₂) or aluminum oxide. The conducting layer 40 can be made of a highly conductive material including copper, silver, molybdenum, aluminum, or indium tin oxide.

The first transparent conducting portions 10 and the second transparent conducting portions 20 can have a square shape, a rectangular shape, a lozenge shape, a circular shape, an elliptical shape, or a polygonal shape. The transparent conducting connection portions 12 can have a strip shape. The cross-sectional shape of the conductive via plug 44 can have a square shape, a rectangular shape, or a circular shape.

The angle defined between the first and second directions can be 30 to 150 degrees, and preferably 90 degrees.

The touch panel of the present invention can have a shield layer (not shown), and is electrically connected to the external unit via the wirings (not shown).

Accordingly, in the bridging structure of the touch panel of the present invention, the planarization of conducting layer can be achieved by forming the conductive via plug in the insulating layer. As a result, the bridging structure is not affected by the step formation in the insulating layer associated with the defective etching and exposure steps. Moreover, the bridging structure of the present invention can solve the prior problems related to the visibility of the conventional bridging structure due to the width of the insulating layer. Therefore, the conductive via plugs are not limited to any specific patterns.

The foregoing description is intended to only provide illustrative ways of implementing the present invention, and should not be construed as limitations to the scope of the present invention. While the foregoing is directed to embodiments of the present invention, other and further embodiments of the invention may thus be devised without departing from the basic scope thereof, and the scope thereof is determined by the claims that follow.

What is claimed is:

1. A bridging structure of a touch panel comprising:
a transparent conducting layer formed on a transparent substrate, wherein the transparent conducting layer comprises a plurality of first transparent conducting portions, a plurality of transparent conducting connection portions, and a plurality of second transparent conducting portions, and the first transparent conducting portions and the second transparent conducting portions are interlaced with each other, and each of the transparent conducting connection portions connects the adjacent first transparent conducting portions to each other along a first direction;
an insulating layer formed on the transparent substrate and covering the transparent conducting connection portions, the first transparent conducting portions and the transparent conducting connection portions being electrically insulated from the second transparent conducting portions by the insulating layer, the insulating layer having a plurality of through-holes located on the second transparent conducting portions; and
a conducting layer formed on the insulating layer, wherein the conducting layer comprises a plurality of conducting connection portions and a plurality of conductive via plugs, and the conducting layer connects the adjacent second transparent conducting portions to each other along a second direction.

2. The bridging structure of the touch panel according to claim 1, wherein material of the first and the second transparent conducting layers comprises indium tin oxide (ITO).

3. The bridging structure of the touch panel according to claim 1, wherein material of the insulating layer comprises silicon dioxide, or aluminum oxide.

4. The bridging structure of the touch panel according to claim 1, wherein the conducting layer is made of a highly conductive material including copper, silver, molybdenum, aluminum, or indium tin oxide.
